(19) United States
(12) Patent Application Publication
(10) Pub. No.: US 2023/0335655 A1
(43) Pub. Date: Oct. 19, 2023

(54) SOLID-STATE IMAGING APPARATUS AND A MANUFACTURING METHOD THEREOF

(71) Applicant: SONY SEMICONDUCTOR SOLUTIONS CORPORATION, KANAGAWA (JP)

(72) Inventors: ATSUSHI TODA, KANAGAWA (JP); SHUNSUKE MARUYAMA, KANAGAWA (JP)

(21) Appl. No.: 18/044,670

(22) PCT Filed: Sep. 7, 2021
(86) PCT No.: PCT/JP2021/032759

§ 371 Date: Mar. 9, 2023

(30) Foreign Application Priority Data
Sep. 17, 2020 (JP) 2020-156734

(51) Int. Cl. H01L 31/0232; H01L 31/0304; H01L 27/146

(52) U.S. Cl. CPC H01L 31/0232; H01L 31/03046; H01L 27/1462

(57) ABSTRACT

[Problem] To perform imaging while suppressing light in a higher-order mode outside of a specific wavelength band. [Solution] A solid-state imaging apparatus includes: a first filter portion including a Fabry-Perot resonator configured to resonate light of a predetermined wavelength range between two reflection surfaces, the first filter portion being configured to selectively transmit light of the predetermined wavelength range; a photoelectric conversion portion configured to photoelectrically convert at least a part of light transmitted through the first filter portion; and a second filter portion arranged between the first filter portion and the photoelectric conversion portion and configured to suppress light of a higher-order mode included in the light transmitted through the first filter portion.

### TECHNICAL FIELD

The present disclosure relates to a solid-state imaging apparatus and a manufacturing method thereof.

### BACKGROUND ART

A light-receiving element for optical communication which handles signals of two wavelengths, namely, a wavelength λ1 and a wavelength λ2, has been proposed (refer to PTL 1). The light-receiving element is provided with a filter having a band gap wavelength of λ1<λg<λ2. Since the filter blocks light of a wavelength shorter than λg and transmits light of a wavelength longer than λg, multi-spectroscopy in which only a narrow band with a full width at half maximum of a given wavelength range is transmitted cannot be performed.

Optical elements which selectively transmit only specific wavelengths include a Fabry-Perot resonator. A Fabry-Perot resonator is capable of reflecting and transmitting light of a plurality of narrow bands within a specific wavelength band.

### CITATION LIST

### Patent Literature

[PTL 1]
Japanese Patent Application Publication No. 2000-36615

### SUMMARY

### Technical Problem

However, a Fabry-Perot resonator may sometimes reflect and transmit light of a higher-order mode outside of the specific wavelength band. Since light of a higher-order mode has a wavelength that differs from an originally intended wavelength band, the light is undesired light. Although undesired light on a long-wavelength side can be suppressed by how the Fabry-Perot resonator is designed, it is not easy to suppress undesired light on a short-wavelength side.

In consideration thereof, an object of the present disclosure is to provide a solid-state imaging apparatus and a manufacturing method thereof which enable imaging to be performed while suppressing light of a higher-order mode outside of a specific wavelength band.

### Solution to Problem

In order to solve the problem described above, the present disclosure provides a solid-state imaging apparatus, including;
a first filter portion including a Fabry-Perot resonator configured to resonate light of
a predetermined wavelength range between two reflection surfaces, the first filter portion being configured to selectively transmit light of the predetermined wavelength range;
a photoelectric conversion portion configured to photoelectrically convert at least a part of light transmitted through the first filter portion; and
a second filter portion arranged between the first filter portion and the photoelectric conversion portion and configured to suppress light of a higher-order mode included in the light transmitted through the first filter portion.

The first filter portion may include a plurality of pixel blocks periodically arranged in a planar direction,
the pixel blocks may each include a plurality of the first filter portions respectively configured to selectively transmit light of a different wavelength range, and
the second filter portion may be configured to suppress light of a higher-order mode included in light transmitted through the plurality of first filter portions.

The second filter portion may include a substrate including a compound semiconductor material.

The substrate may be an InP substrate.

The substrate may have a thickness of 1000 nm or more.

The second filter portion may be arranged between the substrate and the photoelectric conversion portion and may include a buffer layer configured to lattice-match with the substrate.

The buffer layer may include an InGaAsP layer or an InGaAlAs layer.

The buffer layer may have a thickness of 1000 nm or more.

The buffer layer may have a multiple quantum well structure.

The buffer layer may have a quantum structure including at least one of an InP layer, an InGaAs layer, and an InGaP layer.

The buffer layer may have a quantum structure in which an InGaAs layer or an InGaP layer, and an InP layer, are alternately arranged.

The second filter portion may be configured to suppress wavelength components of under 1000 nm included in light transmitted through the first filter portion.

The first filter portion may have a multi-layer film including an amorphous silicon film.

The first filter portion may include resonators configured to perform refractive-index modulation of light in pixel units, and the multi-layer film may be arranged on both surface sides of the resonators.

At least a part of the resonators among the resonators provided in pixel units may include a cavity having intrinsic refractive characteristics.

The present disclosure provides a manufacturing method of a solid-state imaging apparatus, including the steps of;
forming a photoelectric conversion layer on a first principal surface of a substrate including a compound semiconductor material;
reducing a thickness of the substrate by grinding a side of a second principal surface on an opposite side to the first principal surface of the substrate;
forming a first multi-layer film on the second principal surface of the substrate, the first multi-layer film having a first film and a second film with different refractive indices being alternately arranged;
forming a resonator by forming, on the first multi-layer film, a resonator base layer using the first film or the second film as a material,
forming a cavity of a different size for each pixel in the base layer, and filling an inside of the cavity with the material of the second film when the base layer is the first film but filling the inside of the cavity with the material of the first film when the base layer is the second film; and
forming, on the base layer, a second multi-layer film in which the first film and the second film are alternately arranged, wherein
the step of forming a resonator includes the steps of:
forming a plurality of first grooves on the base layer in a first direction on a plane of the base layer;
forming a plurality of second grooves on the base layer in a second direction which intersects with the first direction on the plane of the base layer; and
forming the resonator by filling the plurality of first grooves and the plurality of second grooves with the material of the second film when the base layer is the first film but filling the plurality of first grooves and the plurality of second grooves with the material of the first film when the base layer is the second film.

In the step of reducing a thickness of the substrate, the thickness of the substrate may be set to 1000 nm or more.

A step of forming a buffer layer which lattice-matches with the substrate on the second principal surface of the substrate may be provided after reducing the thickness of the substrate, wherein
the first multi-layer film may be formed on the buffer layer.

In the step of forming a buffer layer, a thickness of the buffer layer may be set to 1000 nm or more.

In the step of forming a buffer layer, a quantum structure in which an InGaAs layer or an InGaP layer, and an InP layer, are alternately arranged may be formed.

### BRIEF DESCRIPTION OF DRAWINGS

FIG. 1 is a sectional view of a solid-state imaging apparatus according to a first embodiment.

FIG. 2 is a schematic perspective view corresponding to one pixel of a resonator.

FIG. 3 is a plan view of a resonator.

FIG. 4 is a diagram showing spectral characteristics of the solid-state imaging apparatus according to the first embodiment.

FIG. 5 is a sectional view of a solid-state imaging apparatus according to a comparative example.

FIG. 6 is a diagram showing spectral characteristics of the solid-state imaging apparatus shown in FIG. 5.

FIG. 7 is a diagram showing a sectional structure of a solid-state imaging apparatus in which a thickness of each layer in a first filter portion is made 1.1 times thicker than a thickness of a corresponding layer in a first filter portion shown in FIG. 1.

FIG. 8 is a diagram showing spectral characteristics of the solid-state imaging apparatus shown in FIG. 7.

FIG. 9A is a sectional view of a solid-state imaging apparatus according to a second embodiment using an InGaAsP layer as a buffer layer.

FIG. 9B is a sectional view of a solid-state imaging apparatus 1 according to the second embodiment using an InGaAlAs layer as a buffer layer.

FIG. 10 is a diagram showing absorption coefficients of InGaAsP, InGaAlAs, and InP with respect to wavelengths.

FIG. 11 is a diagram showing spectral characteristics of the solid-state imaging apparatus shown in FIG. 9A.

FIG. 12 is a sectional view of a solid-state imaging apparatus according to a third embodiment.

FIG. 13A is a diagram showing steps of manufacturing the solid-state imaging apparatus according to the first embodiment.

FIG. 13B is a process chart which continues from FIG. 13A.

FIG. 13C is a process chart which continues from FIG. 13B.

FIG. 13D is a process chart which continues from FIG. 13C.

FIG. 13E is a process chart which continues from FIG. 13D.

FIG. 13F is a process chart which continues from FIG. 13E.

FIG. 14A is a diagram schematically showing an example of a mask used in a first exposure.

FIG. 14B is a diagram schematically showing an example of a mask used in a second exposure.

FIG. 15 is a block diagram showing an example of a schematic configuration of a vehicle control system.

FIG. 16 is an explanatory diagram showing an example of positions at which an external vehicle information detecting portion and an imaging portion are installed.

### DESCRIPTION OF EMBODIMENTS

Embodiments of a solid-state imaging apparatus and a manufacturing method thereof will be described below with reference to the drawings. Although the following description will focus on main components of the solid-state imaging apparatus and the manufacturing method thereof, the solid-state imaging apparatus and the manufacturing method thereof may have components and functions that are not illustrated or described. The following description is not intended to exclude components or functions that are not illustrated or described.

### First Embodiment

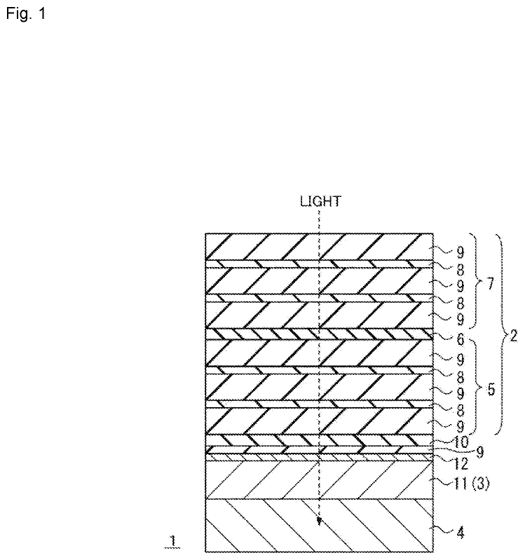

FIG. 1 is a sectional view of a solid-state imaging apparatus 1 according to a first embodiment. The solid-state imaging apparatus 1 shown in FIG. 1 is, for example, a visible-light spectroscopic CMOS (Complementary Metal Oxide Semiconductor) image sensor.

The solid-state imaging apparatus 1 shown in FIG. 1 includes, in order in a sectional direction from a light incident surface side, a first filter portion 2, a second filter portion 3, and a photoelectric conversion portion 4. In addition, the solid-state imaging apparatus 1 shown in FIG. 1 includes a plurality of pixels in a planar direction.

The first filter portion 2 includes a Fabry-Perot resonator which resonates light of a predetermined wavelength range between two reflection surfaces, and the first filter portion 2 selectively transmits light of the predetermined wavelength range. The Fabry-Perot resonator reflects and transmits light of a wavelength λ satisfying a relationship expressed as mλ=2 nL. m represents an order and is an integer equal to or greater than 1. n represents a refractive index of a resonator. L represents a resonator length. A detailed sectional structure of the first filter portion 2 will be described later.

The second filter portion 3 is arranged between the first filter portion 2 and the photoelectric conversion portion 4 and suppresses light of a higher-order mode included in light transmitted through the first filter portion 2. A detailed sectional structure of the second filter portion 3 will be described later.

The photoelectric conversion portion 4 photoelectrically converts at least a part of light transmitted through the first filter portion 2. More specifically, the photoelectric conversion portion 4 photoelectrically converts light after the second filter portion 3 suppresses light of a higher-order mode included in the light transmitted through the first filter portion 2.

The first filter portion 2 includes a plurality of pixel blocks periodically arranged in a planar direction. The pixel blocks each include a plurality of the first filter portions 2 which respectively selectively transmit light of a different wavelength range. The second filter portion 3 suppresses light of a higher-order mode included in light transmitted through the plurality of first filter portions 2.

The first filter portion 2 includes a first multi-layer film 5, a resonator 6, and a second multi-layer film 7 which are arranged in order in a laminating direction from a side of the photoelectric conversion portion 4. For example, the first multi-layer film 5 and the second multi-layer film 7 include an amorphous silicon film 8. More specifically, for example, the first multi-layer film 5 has a laminated structure in which a SiO₂ film 9 and the amorphous silicon film 8 are alternately arranged. A Si₃N₄ layer 10 is provided instead of the amorphous silicon film 8 on a side of the photoelectric conversion portion 4 of the first multi-layer film 5. For example, the second multi-layer film 7 also has a laminated structure in which the SiO₂ film 9 and the amorphous silicon film 8 are alternately arranged.

The resonator 6 performs refractive-index modulation of light in pixel units. The resonator 6 is arranged between the first multi-layer film 5 and the second multi-layer film 7. The resonator 6 resonates only light of a plurality of narrow bands within a specific wavelength band among light transmitted through the second multi-layer film 7. The resonated light is reflected by the first multi-layer film 5 and the second multi-layer film 7 arranged on both surface sides of the resonator 6 and emitted from the side of the first multi-layer film 5. As will be described later, the resonator 6 changes an effective refractive index for each pixel by changing a size of a microstructure per pixel.

The second filter portion 3 includes a substrate including a compound semiconductor material. As a specific example of the material, the second filter portion 3 includes an InP substrate 11. In the present embodiment, the InP substrate 11 is given a thickness of 900 nm or more and desirably 1000 nm or more. Giving the InP substrate 11 a thickness of 900 nm or more prevents a peak of a higher-order mode from appearing in spectral characteristics of the solid-state imaging apparatus 1. The thickness of the InP substrate 11 can be controlled in an etching step of a manufacturing process as will be described later.

The solid-state imaging apparatus 1 shown in FIG. 1 includes an ITO film 12 between the InP substrate 11 and the first multi-layer film 5. The ITO film 12 is a transparent electrode layer and is capable of transmitting, without loss, light having been transmitted through the second multi-layer film 7.

The photoelectric conversion portion 4 is arranged on a side of a surface of the InP substrate 11 opposite to the ITO film 12. For example, the photoelectric conversion portion 4 includes InGaAs. In this manner, in the solid-state imaging apparatus 1 according to the first embodiment, the substrate and the photoelectric conversion portion 4 are formed of a compound semiconductor material. Accordingly, even light in an infrared region can be received.

In the solid-state imaging apparatus 1 according to the present embodiment, the photoelectric conversion portion 4 including InGaAs is lattice-matched with the InP substrate 11. Therefore, while light of a wavelength of 1.7 μm or less is absorbed from the band gap, there is no responsiveness with respect to light of longer wavelengths. Accordingly, single spectral characteristics of only a specific wavelength band are provided and multi-spectroscopy can be performed in the specific wavelength band.

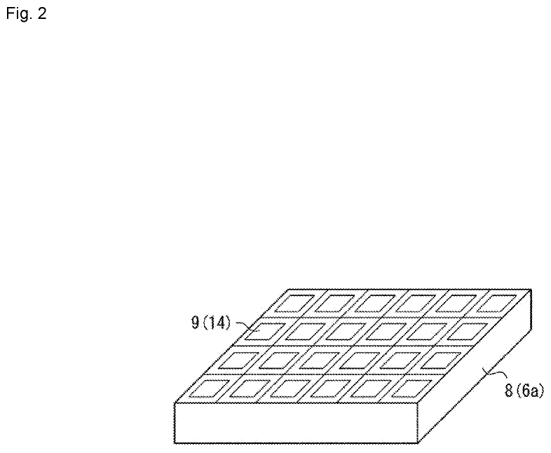

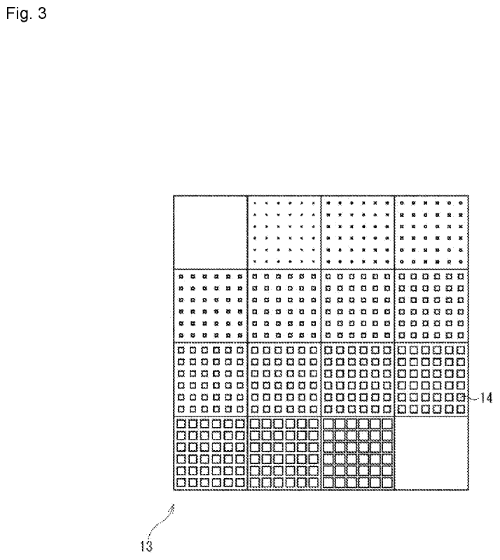

FIG. 2 is a schematic perspective view corresponding to one pixel of the resonator 6, and FIG. 3 is a plan view of the resonator 6. FIG. 3 illustrates a planar layout of the resonator 6 corresponding to a total of 4 pixels×4 pixels=16 pixels. In the example shown in FIG. 3, one pixel block 13 is made up of 4 pixels×4 pixels and a plurality of pixel blocks 13 are arranged vertically and horizontally.

Among the 16 pixels in the pixel block 13 shown in FIG. 3, 15 pixels have a plurality of microstructures 14 for changing an effective refractive index. The microstructure 14 is, for example, a rectangular parallelepiped shape of which an upper surface and a lower surface are squares, and a size of the microstructure 14 differs from one pixel to the next. A plurality of the microstructures 14 are periodically arranged in each pixel. The sizes of the microstructures 14 in each pixel are the same and a planar shape of the microstructures 14 is a square. When the microstructures 14 are irradiated with light, refractive-index modulation in accordance with the size of the microstructures 14 is performed. Accordingly, the resonator 6 can resonate light of a wavelength in a different narrow band for each pixel. The microstructures 14 in each pixel are periodic structures of ½ of the wavelength or smaller and are capable of changing the effective refractive index for each pixel within a range from amorphous silicon to SiO₂.

A base layer 6a of the resonator 6 is the SiO₂ film 9 or the amorphous silicon film 8 in a similar manner to the first multi-layer film 5 and the second multi-layer film 7. When the base layer 6a is the SiO₂ film 9, the microstructures 14 are the amorphous silicon film 8. In addition, as shown in FIG. 2, when the base layer 6a is the amorphous silicon film 8, the microstructures 14 are the SiO₂ film 9. While one pixel among the 16 pixels does not include microstructures 14 in FIG. 3, alternatively, all of the pixels in the pixel block 13 may include microstructures 14.

Just as in FIG. 3, when each of the plurality of pixel blocks 13 includes 16 pixels and sizes of the respective microstructures 14 of the 16 pixels differ from one another, 16-channel spectroscopy can be performed.

Note that FIG. 3 merely represents an example of the microstructures 14 of each pixel in the pixel block 13 and the microstructures 14 of each pixel are not necessarily limited to those shown in FIG. 3. In addition, the number of pixels in the pixel block 13 is not limited to 16 pixels. By increasing the number of pixels in the pixel block 13 and changing the microstructures 14 for each pixel, the number of channels of spectroscopy can be increased.

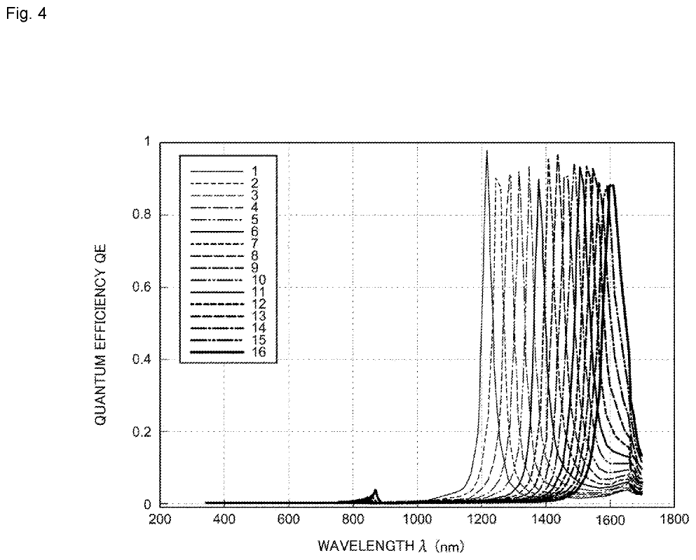

FIG. 4 is a diagram showing spectral characteristics of the solid-state imaging apparatus 1 according to the first embodiment. FIG. 4 shows a simulation result of spectral characteristics when the InP substrate 11 is 1000 nm. In FIG. 4, an abscissa represents wavelength λ (nm) and an ordinate represents quantum efficiency QE. As illustrated, since a peak appears in 16 wavelengths of respectively different narrow bands but a peak is absent from other wavelengths, it is clear that spectral characteristics are superior.

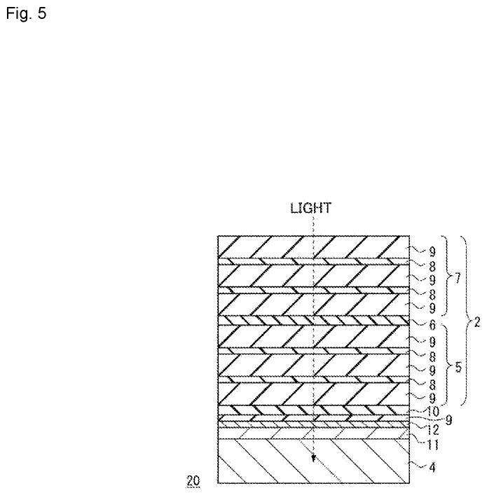

FIG. 5 is a sectional view of a solid-state imaging apparatus 20 according to a comparative example. In the solid-state imaging apparatus 20 shown in FIG. 5, the InP substrate 11 is made thinner than in the solid-state imaging apparatus 1 shown in FIG. 1. Otherwise, there are no structural differences. Compared to the thickness of the InP substrate 11 in the solid-state imaging apparatus 1 shown in FIG. 1 being, for example, 1000 nm, the thickness of the InP substrate 11 in the solid-state imaging apparatus 20 shown in FIG. 5 is, for example, 20 nm.

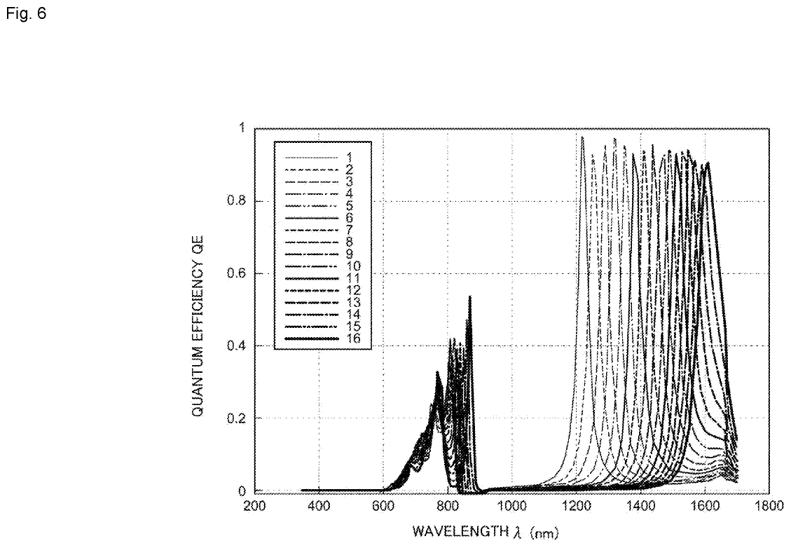

FIG. 6 is a diagram showing spectral characteristics of the solid-state imaging apparatus 20 shown in FIG. 5. FIG. 6 shows a simulation result of spectral characteristics when the thickness of the InP substrate 11 is 20 nm. As illustrated, a peak appears in a higher-order mode near 700 to 800 nm in addition to the peaks of wavelengths of 16-channel spectroscopy. Verification by the present discloser confirmed that, unless the thickness of the InP substrate 11 is 900 nm or more, a peak may possibly appear in a higher-order mode as shown in FIG. 6 and spectral characteristics of the solid-state imaging apparatus 1 may deteriorate.

As described above, in the first embodiment, since the thickness of the InP substrate 11 in the solid-state imaging apparatus 1 provided with a Fabry-Perot resonator is set to 900 nm or more and more desirably to 1000 nm or more, no peaks appear in a higher-order mode in spectral characteristics and multi-spectroscopy in a specific wavelength band can be performed.

### Second Embodiment

In the solid-state imaging apparatus 1 according to the first embodiment, a peak in a higher-order mode may possibly appear in spectral characteristics when a film thickness of the first multi-layer film 5 or the second multi-layer film 7 in the first filter portion 2 constituting the Fabry-Perot resonator changes due to manufacturing variability.

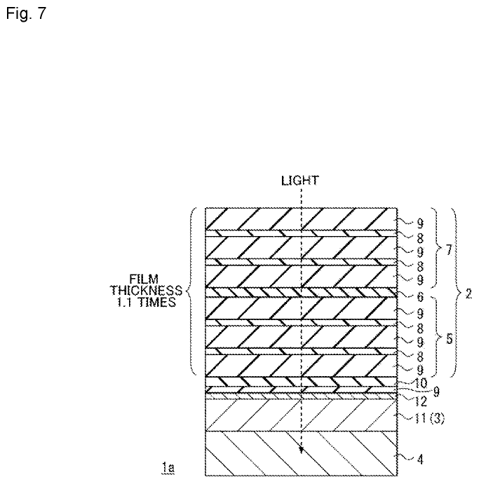

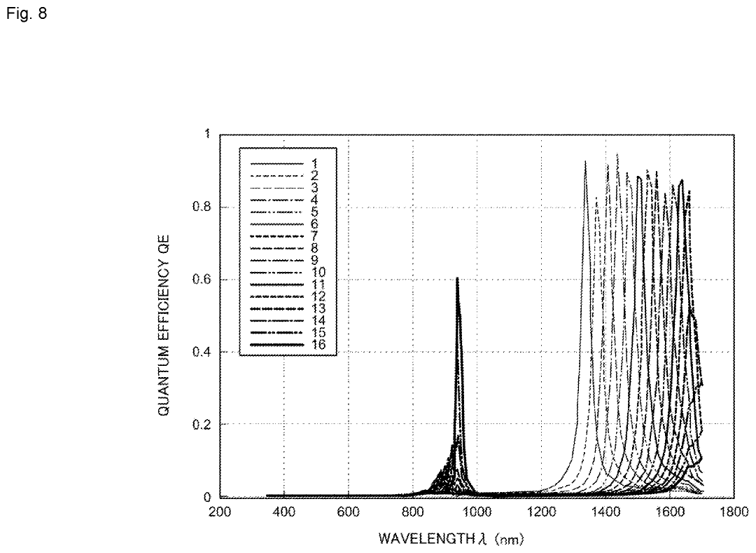

FIG. 7 is a diagram showing a sectional structure of a solid-state imaging apparatus 1a in which a thickness of each layer in the first filter portion 2 is made 1.1 times thicker than a thickness of a corresponding layer in the first filter portion 2 shown in FIG. 1. FIG. 8 shows spectral characteristics of the solid-state imaging apparatus 1a shown in FIG. 7. FIG. 7 shows a simulation result when the thickness of the InP substrate 11 is 1000 nm. As illustrated, even when the InP substrate 11 is made 1000 nm, a peak of a higher-order mode appears in the spectral characteristics.

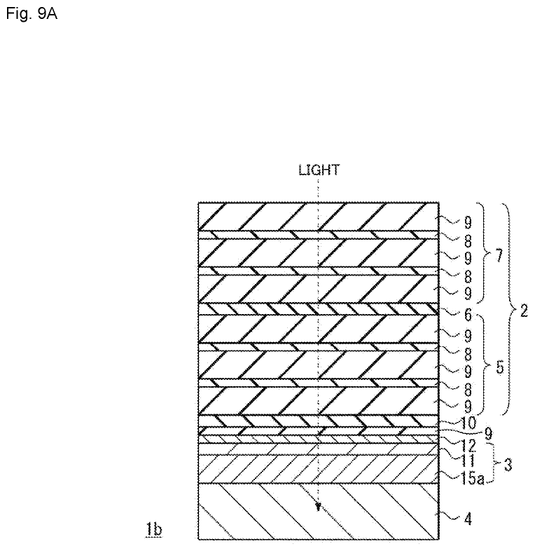

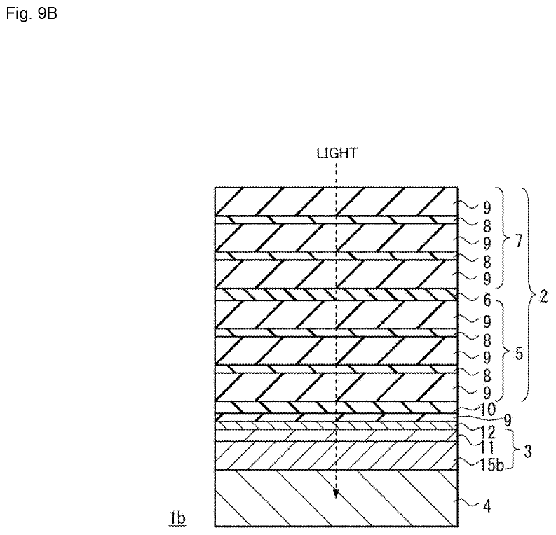

In consideration thereof, a solid-state imaging apparatus 1b according to a second embodiment is newly provided with a buffer layer in the second filter portion 3. FIGS. 9A and 9B are sectional views of the solid-state imaging apparatus 1b according to the second embodiment. A buffer layer 15 in the second filter portion 3 is arranged between the InP substrate 11 and the photoelectric conversion portion 4. As a material of the buffer layer 15, for example, InGaAsP or InGaAlAs is used. FIG. 9A shows an example in which an InGaAsP layer 15a is used as the buffer layer 15 and FIG. 9B shows an example in which an InGaAlAs layer 15b is used as the buffer layer 15.

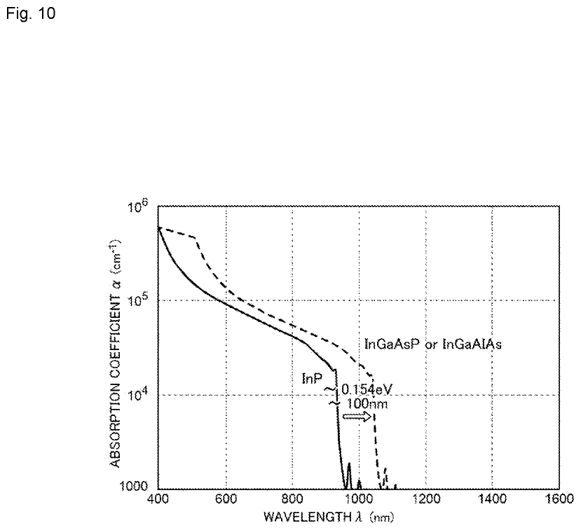

FIG. 10 is a diagram showing absorption coefficients of InGaAsP, InGaAlAs, and InP with respect to wavelengths. As illustrated, with InGaAsP and InGaAlAs, a band gap is smaller by around 0.154 eV and an absorption end is extended toward a long-wavelength side by around 100 nm as compared with InP. Accordingly, a peak of a higher-order mode in spectral characteristics can be suppressed.

In the solid-state imaging apparatus 1 shown in FIGS. 9A and 9B, instead of setting the thickness of the InGaAsP layer 15a or the InGaAlAs layer 15b as the buffer layer 15 to 1000 nm, the thickness of the InP substrate 11 is set to 20 nm. Setting the thickness of the InGaAsP layer 15a or the InGaAlAs layer 15b to 1000 nm enables a similar effect to when the thickness of the InP substrate 11 is set to 1000 nm in the solid-state imaging apparatus 1 according to the first embodiment to be obtained. In the solid-state imaging apparatus 1 according to the second embodiment, the thickness of the InP substrate 11 is arbitrary and may be 20 nm or more.

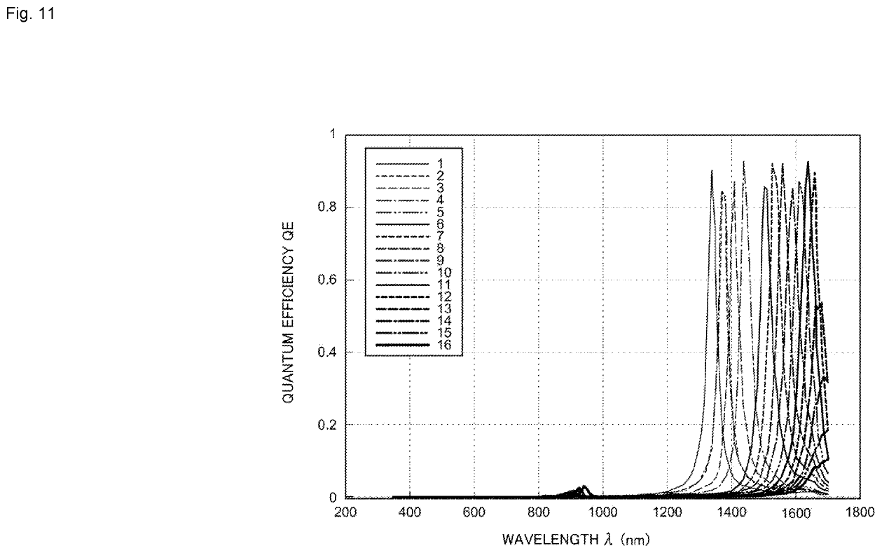

FIG. 11 is a diagram showing spectral characteristics of the solid-state imaging apparatus 1 shown in FIG. 9A. FIG. 11 shows a simulation result when the thickness of each layer in the first filter portion 2 is 1.1 times the thickness of each layer in the first filter portion 2 shown in FIG. 1, the buffer layer 15 is the InGaAsP layer 15a with a thickness of 1000 nm, and the thickness of the InP substrate 11 is 20 nm. As illustrated, providing the buffer layer 15 prevents a peak of a higher-order mode from appearing in the spectral characteristics.

As described above, in the second embodiment, even when a thickness of each layer constituting the Fabry-Perot resonator changes due to manufacturing variability, a peak of a higher-order mode can be prevented from appearing in the spectral characteristics by providing the buffer layer 15 in the second filter portion 3. Accordingly, the solid-state imaging apparatus 1 according to the second embodiment is robust with respect to manufacturing variability and improvements in reliability and yield can be achieved.

### Third Embodiment

Compound semiconductors such as InGaAsP and InGaAlAs have a problem in that an immiscible region (a miscibility gap) is readily created. When an immiscible region is created, a deviation occurs in a band gap or an absorption end of light and, in some cases, a peak in a higher-order mode may appear in spectral characteristics. In consideration thereof, in a third embodiment, the buffer layer 15 adopts a layer configuration which prevents an immiscible region from occurring.

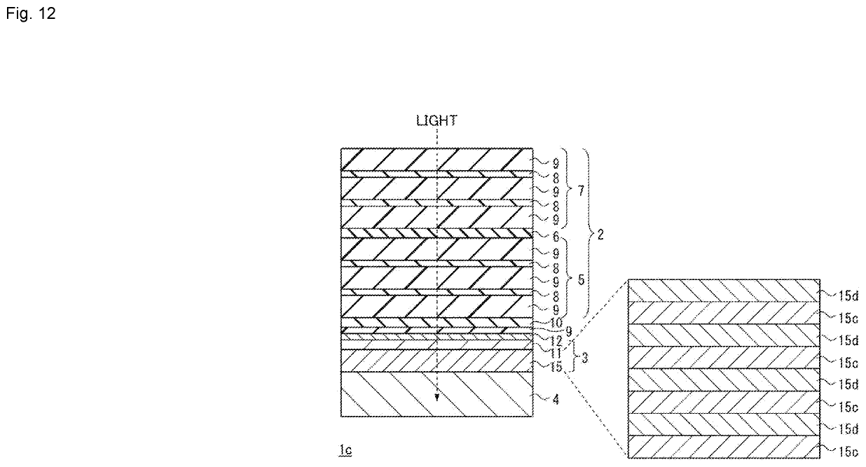

FIG. 12 is a sectional view of a solid-state imaging apparatus 1c according to the third embodiment. In the solid-state imaging apparatus 1c shown in FIG. 12, the buffer layer 15 in the second filter portion 3 adopts a multiple quantum well (MQW) structure.

More specifically, the buffer layer 15 according to the present embodiment includes at least one of an InP layer 15c, an InGaAs layer 15d, and an InGaP layer. For example, the buffer layer 15 according to the present embodiment has a multiple quantum well structure in which the InGaAs layer 15d or the InGaP layer and the InP layer 15c are alternately arranged. In the example shown in FIG. 12, the buffer layer 15 has a multiple quantum well structure in which the InGaAs layer 15d and the InP layer 15c are alternately arranged.

By giving the buffer layer 15 a multiple quantum well structure as shown in FIG. 12, an immiscible region is no longer created. The InGaAs layer 15d can be lattice-matched with the InP substrate 11 so that crystal defects (misfit dislocations) no longer occur. Therefore, a dark current is reduced, S/N is increased, and quality of a captured image of the solid-state imaging apparatus 1 improves. In addition, while a quantum level is formed in a multiple quantum well structure, by reducing an energy gap of a quantum level between the valence band and the conduction band by around 0.154 eV from an energy gap of InP, an absorption end of light can be shifted to a long-wavelength side by around 100 nm from InP. Accordingly, a peak of a higher-order mode can be prevented from appearing in spectral characteristics in a similar manner to the second embodiment.

As described above, in the third embodiment, since the buffer layer 15 provided in the second filter portion 3 is given a multiple quantum well structure, there is no longer a risk of an immiscible region being created in the buffer layer 15, a band gap or an absorption end of light no longer deviates, a peak of a higher-order mode no longer appears in spectral characteristics in a similar manner to the second embodiment and, in addition, robustness against manufacturing variability is attained.

### Fourth Embodiment

A fourth embodiment features manufacturing steps of the solid-state imaging apparatus 1 according to the first to third embodiments.

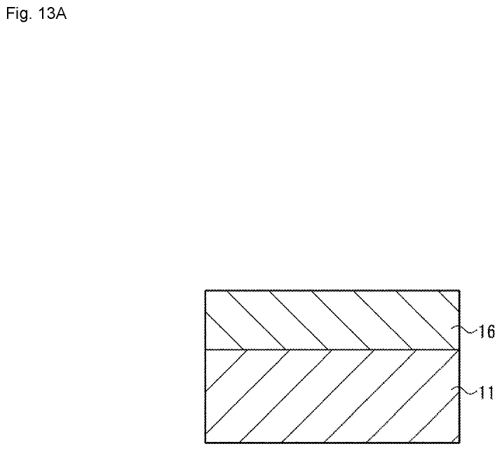

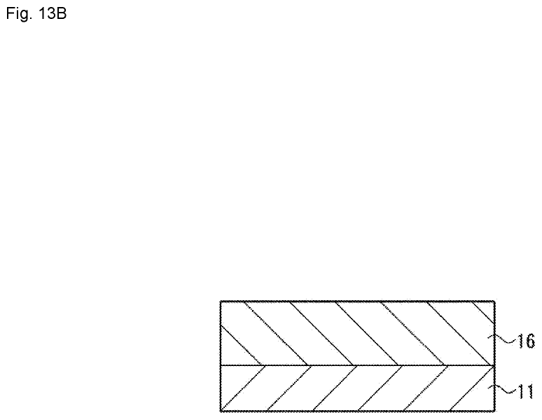

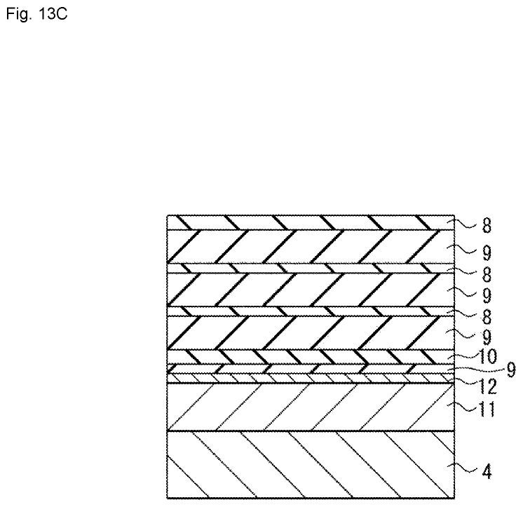

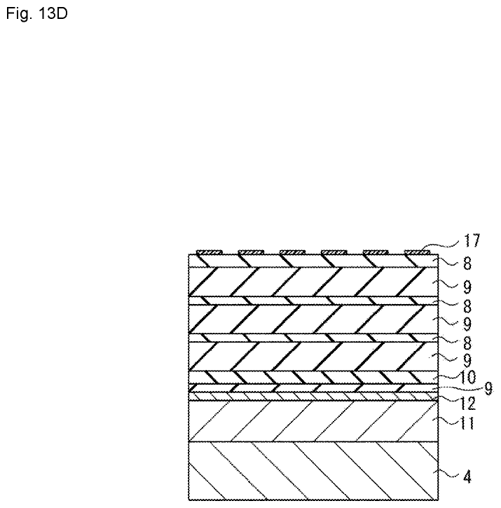

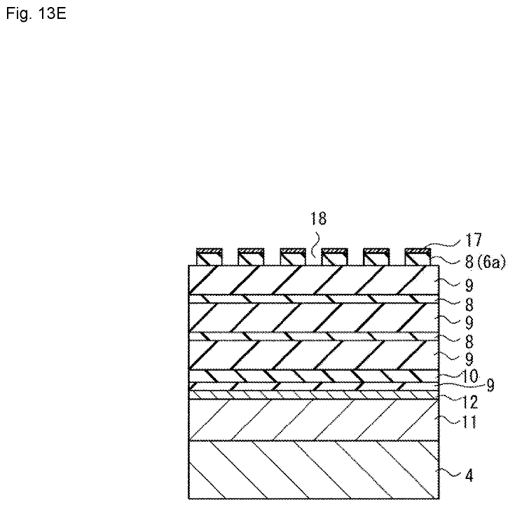

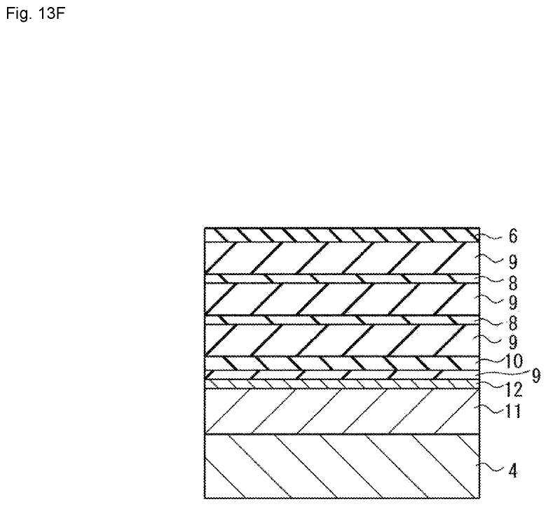

FIGS. 13A to 13F are diagrams showing steps of manufacturing the solid-state imaging apparatus 1 according to the first embodiment. First, as shown in FIG. 13A, a p-InGaAs crystal 16 to become the photoelectric conversion portion 4 is grown on the InP substrate 11. For example, crystal growth can be performed by metal-organic chemical vapor deposition or molecular beam epitaxy. Alternatively, other methods may be used.

When fabricating the solid-state imaging apparatus 1 shown in FIGS. 9A and 9B, a p-InGaAs crystal is grown on the InP substrate 11 after forming the InGaAs layer 15d or the InGaAlAs layer 15b to become the buffer layer 15.

Next, as shown in FIG. 13B, a surface of the InP substrate 11 on an opposite side to the p-InGaAs crystal 16 is thinned to a desired thickness by wet etching or dry etching. In this case, the thickness of the InP substrate 11 is adjusted to approximately 1000 nm.

While the thickness of the InP substrate 11 is not particularly limited in the solid-state imaging apparatus 1 according to the second embodiment, the thickness of the buffer layer 15 is set to around 1000 nm. When fabricating the solid-state imaging apparatus 1 shown in FIG. 9A or 9B, the thickness of the InP substrate 11 may be reduced to around 20 nm.

Next, as shown in FIG. 13C, the second filter portion 3 is formed on top of the thinned InP substrate 11. More specifically, after forming the first multi-layer film 5, the resonator 6 is formed on top of the first multi-layer film 5 and the second multi-layer film 7 is formed on the resonator 6. The first multi-layer film 5 and the second multi-layer film 7 can be formed by chemical vapor deposition (CVD), electron-beam deposition, sputtering, or the like. The first multi-layer film 5 and the second multi-layer film 7 are laminated films in which the amorphous silicon film 8 and the SiO₂ film 9 are alternately formed.

The first multi-layer film 5, the resonator 6, and the second multi-layer film 7 constitute a Fabry-Perot resonator. Since the resonator 6 has microstructures 14, the resonator 6 is formed using a lithographic technique. For example, in the resonator 6, as shown in FIG. 13D, with the amorphous silicon film 8 as the base layer 6a, a photoresist 17 is applied and patterned, and exposure and development is performed. Next, as shown in FIG. 13E, dry etching is performed to form a cavity 18 for the microstructures 14. Next, as shown in FIG. 13F, an inside of the cavity 18 is filled with the SiO₂ film 9. Subsequently, an upper surface of the amorphous silicon film 8 may be planarized by CMP (Chemical Vapor Deposition) or the like. The base layer 6a of the resonator 6 may be the SiO₂ film 9. In this case, the cavity is filled with the amorphous silicon film 8. The second multi-layer film 7 is formed on top of the resonator 6 and, accordingly, the solid-state imaging apparatus 1 provided with a Fabry-Perot resonator as shown in FIG. 1 is fabricated.

When a mask used in lithography for forming the microstructures 14 of the resonator 6 has a rectangular hole portion, performing exposure and development through the hole portion may cause corners of the microstructures 14 with square shapes to become round. This is because light is diffracted at four corners of the hole portion of the photomask and corners of the exposed portion do not become steep angles.

A conceivable method of preventing corners of the microstructures 14 from becoming round involves performing the exposure step twice using two masks.

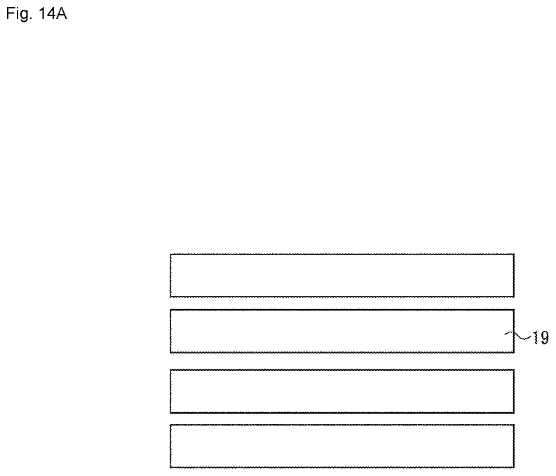

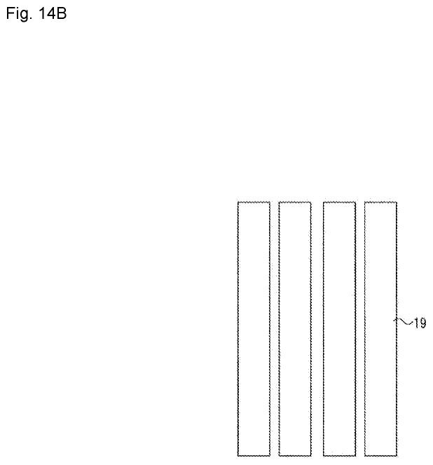

FIG. 14A is a diagram schematically showing an example of a mask 19 used in a first exposure, and FIG. 14B is a diagram schematically showing an example of the mask 19 used in a second exposure. Gaps between the masks 19 shown in FIGS. 14A and 14B indicate locations to be exposed. The locations to be exposed are removed by etching and grooves are formed. Due to the exposure, development, and etching for the first time shown in FIG. 14A, a plurality of first grooves extending in a first direction are formed. Due to subsequently-performed exposure, development, and etching for the second time shown in FIG. 14B, a plurality of second grooves extending in a second direction which intersects with the first direction are formed. Regions enclosed by the first grooves and the second grooves become portions of the microstructures 14.

As shown in FIGS. 14A and 14B, performing the exposure step twice using two masks 19 enables the four corners of the microstructures 14 to be made steep.

The resist used in lithography may be either a negative type or a positive type. When using resists of both negative and positive types, two masks 19 including an inverted mask 19 may be used.

Although omitted in FIGS. 13A to 13E, a read electrode and a read circuit of a pixel signal may be provided on a side of a surface opposite to the InP substrate 11 of the photoelectric conversion portion 4. For example, a read circuit formed on a silicon substrate may be bonded by a Cu—Cu bond, a bump, or the like to the InP substrate 11 on which the photoelectric conversion portion 4 is formed.

Although omitted in FIGS. 13A to 13E, after the step of FIG. 13E ends, a moth-eye structure may be provided on a side of a light incident surface which is the upper surface of the second multi-layer film 7. Providing a moth-eye structure enables surface reflection of the light incident surface to be suppressed and spectral oscillation to be reduced. A moth-eye structure is a structure having a plurality of projections with sharp-pointed shapes arranged on the light incident surface at a pitch equal to or shorter than a wavelength λ and, particularly, at a pitch equal to or shorter than ⅓×λ. A moth-eye structure can be formed by preparing, in advance, a mold in which a concave-convex pattern is formed, pressing the mold on an upper surface of an ultraviolet-curing resin layer formed on the second multi-layer film 7, and irradiating the mold with ultraviolet light.

Surface reflection of a light incident surface may be suppressed by methods other than a moth-eye structure. For example, after the step of FIG. 13E ends, an optical lens member formed of a transparent resin material or the like may be provided on a side of a light incident surface which is the upper surface of the second multi-layer film 7. For example, an optical lens member is provided with the pixel block 13 shown in FIG. 3 as a unit. Providing the optical lens member enables directions of light in which incident light is incident to each pixel in the pixel block 13 to be aligned.

As described above, according to the fourth embodiment, performing exposure, development, and etching using two masks with different aperture directions when forming the microstructures 14 of the resonator 6 enables the four corners of the microstructures 14 to be made into steep shapes. Therefore, a failure in which the four corners of the resonator 6 become round no longer occurs and desired refractive-index modulation can be performed.

### Fifth Embodiment

The solid-state imaging apparatuses 1, 1a, 1b, and 1c according to the first to fourth embodiments can be used in a variety of applications. Applications in which the solid-state imaging apparatuses 1 according to the first to fourth embodiments can be used are determined by a wavelength range and a peak full width at half maximum (FWHM) of spectral spectroscopy. The peak full width at half maximum FWHM of spectroscopy of the Fabry-Perot resonator provided in the solid-state imaging apparatuses 1 according to the first to fourth embodiments is low at 50 nm or less and enables application over a wide frequency range. For example, in agricultural applications, the solid-state imaging apparatuses 1 according to the first to fourth embodiments can be used in vegetation management. Specifically, by mounting a camera incorporating the solid-state imaging apparatuses 1, 1a, 1b, and 1c according to the first to fourth embodiments to a small-sized unmanned flying body (drone) and observing a state of growth of agricultural crops from above, the growth of crops can be managed and controlled.

In addition, in on-vehicle applications, the solid-state imaging apparatuses 1, 1a, 1b, and 1c according to the first to fourth embodiments can be used to distinguish objects such as concrete and asphalt from human beings. Furthermore, the solid-state imaging apparatuses 1, 1a, 1b, and 1c according to the first to fourth embodiments can also be used in analyses of components of various materials such as food, pharmaceuticals, and resins and in material identification. In addition, for example, since absorption by water occurs at wavelengths near 1400 nm, the solid-state imaging apparatuses 1, 1a, 1b, and 1c according to the first to fourth embodiments can also be used to measure water content.

### 4. Application Example

The technique according to the present disclosure can be applied to various products. For example, the technique according to the present disclosure may be implemented as an apparatus mounted on any kind of mobile body such as an automobile, an electric vehicle, a hybrid electric vehicle, a motorcycle, a bicycle, a personal mobility, an airplane, a drone, a ship, a robot, a construction machine, or an agricultural machine (tractor).

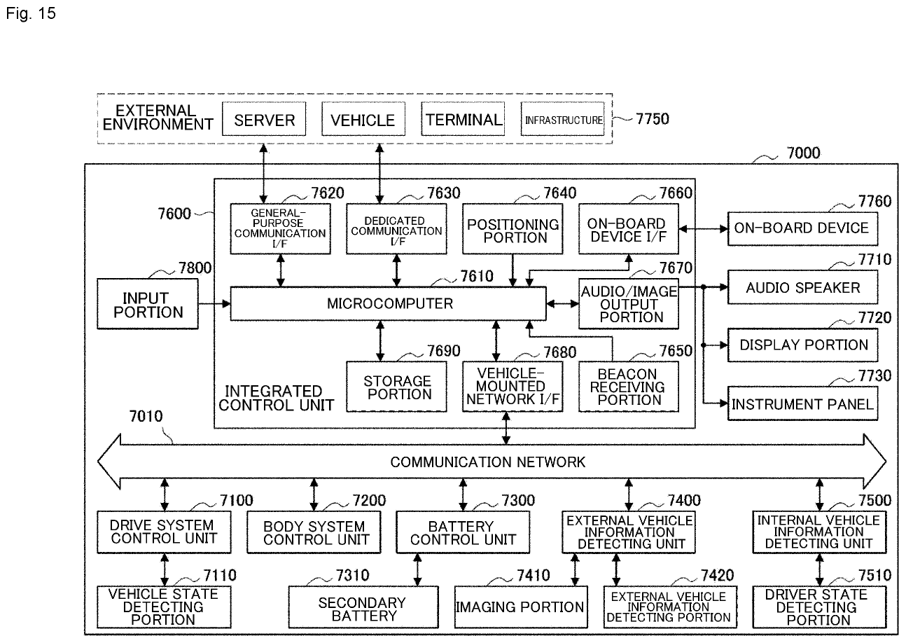

FIG. 15 is a block diagram showing a schematic configuration example of a vehicle control system 7000, which is an example of a mobile body control system to which the technique according to the present disclosure can be applied. The vehicle control system 7000 includes a plurality of electronic control units connected via a communication network 7010. In the example shown in FIG. 15, the vehicle control system 7000 includes a drive system control unit 7100, a body system control unit 7200, a battery control unit 7300, an external vehicle information detecting unit 7400, an internal vehicle information detecting unit 7500, and an integrated control unit 7600. The communication network 7010 for connecting these plurality of control units may be an onboard communication network based on any standard such as a CAN (Controller Area Network), a LIN (Local Interconnect Network), a LAN (Local Area Network), or FlexRay (registered trademark).

Each control unit includes a microcomputer that performs arithmetic processing according to various programs, a storage portion that stores programs executed by the microcomputer, parameters used for various arithmetic operations, and the like, and a drive circuit that drives various control object apparatuses. Each control unit includes a network I/F for communicating with other control units via the communication network 7010 and a communication I/F for communicating with apparatuses, sensors, or the like inside or outside the vehicle through wired communication or wireless communication. In FIG. 15, a microcomputer 7610, a general-purpose communication I/F 7620, a dedicated communication I/F 7630, a positioning portion 7640, a beacon receiving portion 7650, an on-board device I/F 7660, an audio/video output portion 7670, a vehicle-mounted network I/F 7680, and a storage portion 7690 are illustrated as functional components of the integrated control unit 7600. Other control units similarly include a microcomputer, a communication I/F, a storage unit, and the like.

The drive system control unit 7100 controls the operation of apparatuses related to a drive system of the vehicle according to various programs. For example, the drive system control unit 7100 functions as a control apparatus for a driving force generation apparatus for generating a driving force of the vehicle such as an internal combustion engine or a drive motor, a driving force transmission mechanism for transmitting the driving force to wheels, a steering mechanism for adjusting a steering angle of the vehicle, and a braking apparatus for generating a braking force of the vehicle. The drive system control unit 7100 may have a function as a control apparatus for an ABS (Antilock Brake System) or ESC (Electronic Stability Control).

A vehicle state detecting portion 7110 is connected to the drive system control unit 7100. The vehicle state detecting portion 7110 includes, for example, at least one of a gyro sensor that detects an angular velocity of an axial rotation motion of a vehicle body, an acceleration sensor that detects an acceleration of a vehicle, and sensors for detecting an amount of operation with respect to an accelerator pedal, an amount of operation with respect to a brake pedal, a steering angle of a steering wheel, an engine speed, a rotation speed of wheels, and the like. The drive system control unit 7100 performs arithmetic processing using a signal input from the vehicle state detecting portion 7110 to control an internal combustion engine, a drive motor, an electronic power steering apparatus, a brake apparatus, and the like.

The body system control unit 7200 controls operations of various apparatuses equipped in the vehicle body in accordance with various programs. For example, the body system control unit 7200 functions as a control apparatus of a keyless entry system, a smart key system, a power window apparatus, or various lamps such as a head lamp, a back lamp, a brake lamp, a turn indicator, and a fog lamp. In this case, radio waves emitted from a portable device that substitutes as a key or signals of various switches can be input to the body system control unit 7200. The body system control unit 7200 receives inputs of the radio waves or signals and controls a door lock apparatus, a power window apparatus, lamps, and the like of the vehicle.

The battery control unit 7300 controls a secondary battery 7310 which is a power supply source of a driving motor in accordance with various programs. For example, information such as a battery temperature, a battery output voltage, or a remaining capacity of a battery is input from a battery apparatus including the secondary battery 7310 to the battery control unit 7300. The battery control unit 7300 performs arithmetic processing using such a signal and performs temperature adjustment control of the secondary battery 7310 or control of a cooling apparatus or the like equipped in the battery apparatus.

The external vehicle information detecting unit 7400 detects external information of the vehicle on which the vehicle control system 7000 is mounted. For example, at least one of an imaging portion 7410 and an external vehicle information detecting portion 7420 is connected to the external vehicle information detecting unit 7400. The imaging portion 7410 includes at least one of a ToF (Time Of Flight) camera, a stereo camera, a monocular camera, an infrared camera, and other cameras. For example, the external vehicle information detecting portion 7420 includes at least one of an environmental sensor for detecting present weather or atmospheric phenomena and an ambient information detection sensor for detecting other vehicles, obstacles, pedestrians, and the like around the vehicle on which the vehicle control system 7000 is mounted.

The environmental sensor may be, for example, at least one of a raindrop sensor that detects rainy weather, a fog sensor that detects fog, a sunshine sensor that detects a degree of sunshine, and a snow sensor that detects snowfall. The ambient information detection sensor may be at least one of an ultrasonic sensor, a radar apparatus, and a LIDAR (Light Detection and Ranging or Laser Imaging Detection and Ranging) apparatus. The imaging portion 7410 and the external vehicle information detecting portion 7420 may be included as independent sensors or apparatuses, or may be included as an apparatus in which a plurality of sensors or apparatuses are integrated.

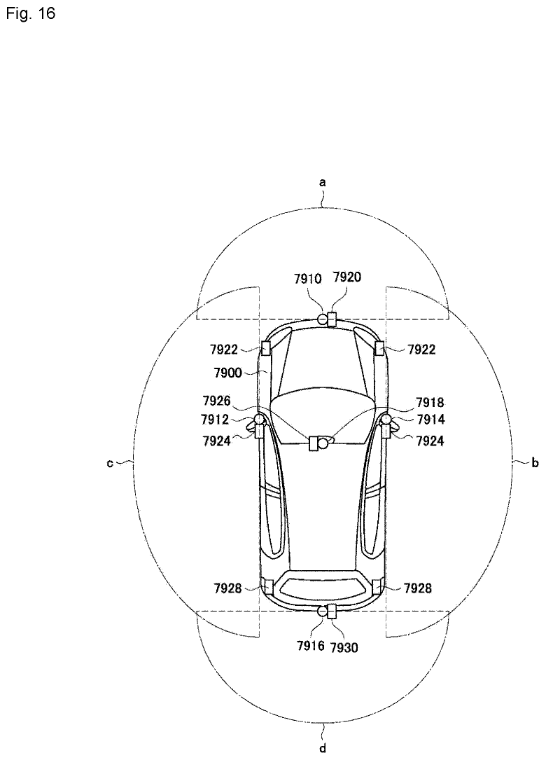

In this case, FIG. 16 shows an example of installation positions of the imaging portion 7410 and the external vehicle information detecting portion 7420. Imaging portions 7910, 7912, 7914, 7916, and 7918 are provided at, for example, at least one of a front nose, side mirrors, a rear bumper, a back door, and an upper part of a windshield in a vehicle cabin of a vehicle 7900. The imaging portion 7910 provided on the front nose and the imaging portion 7918 provided on the upper part of the windshield in the vehicle cabin mainly acquire an image in front of the vehicle 7900. The imaging portions 7912 and 7914 provided on the side mirrors mainly acquire images of the sides of the vehicle 7900. The imaging portion 7916 provided on the rear bumper or the back door mainly acquires an image of the rear of the vehicle 7900. The imaging portion 7918 provided on the upper part of the windshield in the vehicle cabin is mainly used for detection of a preceding vehicle, a pedestrian, an obstacle, a traffic light, a traffic sign, a lane, or the like.

In FIG. 16, an example of photographing ranges of the respective imaging portions 7910, 7912, 7914, and 7916 is shown. An imaging range a indicates an imaging range of the imaging portion 7910 provided on the front nose, imaging ranges b and c respectively indicate imaging ranges of the imaging portions 7912 and 7914 provided on the side mirrors, and an imaging range d indicates an imaging range of the imaging portion 7916 provided on the rear bumper or the back door. For example, a bird's-eye image of the vehicle 7900 as viewed from above can be obtained by superimposing image data captured by the imaging portions 7910, 7912, 7914, and 7916.

External vehicle information detecting portions 7920, 7922, 7924, 7926, 7928, and 7930 provided in the front, the rear, the side, a corner, and an upper part of the windshield in the vehicle cabin of the vehicle 7900 may be, for example, ultrasonic sensors or radar apparatuses. The external vehicle information detecting portions 7920, 7926, and 7930 provided at the front nose, the rear bumper, the back door, and the upper part of the windshield in the vehicle cabin of the vehicle 7900 may be, for example, LIDAR apparatuses. These external vehicle information detecting portions 7920 to 7930 are mainly used for detection of a preceding vehicle, a pedestrian, an obstacle, or the like.

Returning to FIG. 15, the description will be continued. The external vehicle information detecting unit 7400 causes the imaging portion 7410 to capture an image of the outside of the vehicle and receives the captured image data. In addition, the external vehicle information detecting unit 7400 receives detection information from the connected external vehicle information detecting portion 7420. When the external vehicle information detecting portion 7420 is an ultrasonic sensor, a radar apparatus, or a LIDAR apparatus, the external vehicle information detecting unit 7400 transmits ultrasonic waves, electromagnetic waves, or the like and receives information on received reflected waves. The external vehicle information detecting unit 7400 may perform object detection processing or distance detection processing with respect to a person, a vehicle, an obstacle, a sign, a character on a road surface, or the like based on the received information. The external vehicle information detecting unit 7400 may perform environment recognition processing for recognizing rainfall, fog, a road surface situation, and the like based on the received information. The external vehicle information detecting unit 7400 may calculate a distance to an object outside the vehicle based on the received information.

Furthermore, the external vehicle information detecting unit 7400 may perform image recognition processing or distance detection processing for recognizing a person, a vehicle, an obstacle, a sign, a character on a road surface, or the like based on the received image data. The external vehicle information detecting unit 7400 may perform processing such as distortion correction or alignment with respect to the received image data, and combine pieces of image data captured by the different imaging portions 7410 to generate a bird's-eye image or a panoramic image. The external vehicle information detecting unit 7400 may perform viewpoint conversion processing using the pieces of image data captured by the different imaging portions 7410.

The internal vehicle information detecting unit 7500 detects information inside the vehicle. For example, a driver state detecting portion 7510 that detects a driver's state is connected to the internal vehicle information detecting unit 7500. The driver state detecting portion 7510 may include a camera that images a driver, a biological sensor that detects biological information of the driver, or a microphone that collects a sound in the vehicle cabin. The biological sensor is provided on, for example, a seat surface, a steering wheel, or the like and detects biological information of an occupant sitting on the seat or the driver holding the steering wheel. The internal vehicle information detecting unit 7500 may calculate the degree of fatigue or the degree of concentration of the driver or determine whether the driver is not drowsing based on detected information input from the driver state detecting portion 7510. The internal vehicle information detecting unit 7500 may perform processing such as noise canceling processing on the collected audio signals.

The integrated control unit 7600 controls an overall operation in the vehicle control system 7000 according to various programs. An input portion 7800 is connected to the integrated control unit 7600. The input portion 7800 is realized by an apparatus on which an occupant can perform an input operation such as a touch panel, a button, a microphone, a switch, or a lever. Data obtained by recognizing a sound input by the microphone may be input to the integrated control unit 7600. The input portion 7800 may be, for example, a remote control apparatus using infrared light or other radio waves or may be an externally connected apparatus such as a mobile phone or a PDA (Personal Digital Assistant) corresponding to an operation of the vehicle control system 7000. For example, the input portion 7800 may be a camera, in which case an occupant can input information by a gesture. Alternatively, data obtained by detecting a motion of a wearable apparatus worn by an occupant may be input. Furthermore, the input portion 7800 may include, for example, an input control circuit or the like that generates an input signal based on information input by an occupant or the like using the foregoing input portion 7800 and outputs the input signal to the integrated control unit 7600. The occupant or the like operates the input portion 7800 to input various kinds of data to the vehicle control system 7000 or instruct the vehicle control system 7000 to perform processing operations.

The storage portion 7690 may include a ROM (Read Only Memory) that stores various programs executed by the microcomputer and a RAM (Random Access Memory) that stores various parameters, calculation results, sensor values, or the like. In addition, the storage portion 7690 may be realized by a magnetic storage device such as an HDD (Hard Disc Drive), a semiconductor storage device, an optical storage device, a magneto-optical storage device, or the like.

The general-purpose communication I/F 7620 is a general-purpose communication I/F that mediates communication with various devices present in an external environment 7750. The general-purpose communication I/F 7620 may have, implemented therein, a cellular communication protocol such as GSM (registered trademark) (Global System of Mobile communications), WiMAX (registered trademark), LTE (registered trademark) (Long Term Evolution), or LTE-A (LTE-Advanced), or other wireless communication protocols such as wireless LAN (also referred to as Wi-Fi (registered trademark)) or Bluetooth (registered trademark). The general-purpose communication I/F 7620 may connect to, for example, a device (for example, an application server or a control server) present on an external network (for example, the Internet, a cloud network, or a business-specific network) via a base station or an access point. Furthermore, the general-purpose communication I/F 7620 may connect to a terminal present near the vehicle (for example, a terminal of a driver, a pedestrian, a store, or a MTC (Machine Type Communication) terminal) using, for example, peer to peer (P2P) technology.

The dedicated communication I/F 7630 is a communication I/F that supports a communication protocol designed for use in vehicles. In the dedicated communication I/F 7630, for example, WAVE (Wireless Access in Vehicle Environment) being a combination of IEEE 802.11p of a lower layer and IEEE 1609 of an upper layer, DSRC (Dedicated Short Range Communications), or a standard protocol such as a cellular communication protocol may be implemented. The dedicated communication I/F 7630 typically performs V2X communication which is a concept that includes one or more of vehicle-to-vehicle communication, vehicle-to-infrastructure communication, vehicle-to-home communication, and vehicle-to-pedestrian communication.

The positioning portion 7640 receives, for example, a GNSS (Global Navigation Satellite System) signal from a GNSS satellite (for example, a GPS (Global Positioning System) signal from a GPS satellite), executes positioning, and generates position information including a latitude, longitude, and altitude of the vehicle. The positioning portion 7640 may specify a current position by exchanging signals with a wireless access point, or may acquire position information from a terminal such as a mobile phone, PHS, or smartphone having a positioning function.

The beacon receiving portion 7650 receives radio waves or electromagnetic waves transmitted from a radio station or the like installed on a road, and acquires information such as a current position, traffic jam, no thoroughfare, or required time. A function of the beacon receiving portion 7650 may be included in the dedicated communication I/F 7630 described above.

The on-board device I/F 7660 is a communication interface that mediates connections between the microcomputer 7610 and various on-board devices 7760 present in the vehicle. The on-board device I/F 7660 may establish a wireless connection using a wireless communication protocol such as wireless LAN, Bluetooth (registered trademark), NFC (Near Field Communication), or WUSB (Wireless USB). Furthermore, the on-board device I/F 7660 may establish a wired connection such as a USB (Universal Serial Bus), HDMI (registered trademark) (High-Definition Multimedia Interface), or MHL (Mobile High-definition Link) via a connection terminal (not illustrated) (and a cable if necessary). The on-board devices 7760 may include, for example, at least one of a mobile apparatus or a wearable apparatus of an occupant and an information apparatus carried in or attached to the vehicle. Furthermore, the on-board devices 7760 may include a navigation apparatus that searches for a route to an arbitrary destination. The on-board device I/F 7660 exchanges control signals or data signals with the on-board devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 according to various programs based on information acquired via at least one of the general-purpose communication I/F 7620, the dedicated communication I/F 7630, the positioning portion 7640, the beacon receiving portion 7650, the on-board device I/F 7660, and the vehicle-mounted network I/F 7680. For example, the microcomputer 7610 may calculate a control object value of the driving force generation apparatus, the steering mechanism, or the braking apparatus based on the acquired information inside and outside the vehicle, and output a control command to the drive system control unit 7100. For example, the microcomputer 7610 may perform cooperative control for the purpose of realization of functions of an ADAS (Advanced Driver Assistance System) including vehicle collision avoidance or impact mitigation, car-following driving based on an inter-vehicle distance, constant-speed driving, vehicle collision warning, vehicle lane deviation warning, and the like. Furthermore, the microcomputer 7610 may perform cooperative control for the purpose of, for example, automated driving in which a vehicle travels autonomously without relying on an operation of the driver, by controlling the driving force generation device, the steering mechanism, the braking device, or the like based on acquired information on the surroundings of the vehicle.

The microcomputer 7610 may generate three-dimensional distance information between the vehicle and objects such as surrounding structures or people based on information acquired via at least one of the general-purpose communication I/F 7620, the dedicated communication I/F 7630, the positioning portion 7640, the beacon receiving portion 7650, the on-board device I/F 7660, and the vehicle-mounted network I/F 7680 and may generate local map information including information on surroundings of a present position of the vehicle. In addition, the microcomputer 7610 may predict danger such as a collision of the vehicle, an approach by a pedestrian, or entry into a closed-off road based on the acquired information and may generate a warning signal. The warning signal may be, for example, a signal for generating a warning sound or turning on a warning lamp.

The audio/video output portion 7670 transmits an output signal of at least one of audio and video to an output apparatus capable of visually or audibly notifying an occupant of the vehicle or the outside of the vehicle of information. In the example of FIG. 15, an audio speaker 7710, a display portion 7720, and an instrument panel 7730 are exemplified as the output apparatus. The display portion 7720 may include at least one of, for example, an onboard display and a head-up display. The display portion 7720 may have an AR (Augmented Reality) display function. The output apparatus may be an apparatus other than the above such as headphones, a spectacle-type display worn by an occupant, or another wearable device, a projector, or a lamp. When the output apparatus is a display apparatus, the display apparatus visually displays results obtained through various kinds of processing performed by the microcomputer 7610 or information received from another control unit in various formats such as a text, an image, a table, and a graph. When the output apparatus is an audio output apparatus, the audio output apparatus converts an audio signal constituted of reproduced sound data, acoustic data, or the like into an analog signal and outputs the analog signal auditorially.

In the example shown in FIG. 15, at least two control units connected via the communication network 7010 may be integrated as one control unit. Alternatively, each control unit may be constituted of a plurality of control units. Furthermore, the vehicle control system 7000 may include other control units (not illustrated). Furthermore, in the above description, a part of or all of the functions performed by any of the control units may be performed by another control unit. That is, predetermined calculation processing may be performed by any one of the control units as long as information is transmitted and received via the communication network 7010. Similarly, a sensor or apparatus connected to any one of the control units may be connected to another control unit, and a plurality of control units may transmit or receive detection information to and from each other via the communication network 7010.

The present technique may be configured as follows.
(1) A solid-state imaging apparatus, including:
a first filter portion including a Fabry-Perot resonator configured to resonate light of a predetermined wavelength range between two reflection surfaces, the first filter portion being configured to selectively transmit light of the predetermined wavelength range;
a photoelectric conversion portion configured to photoelectrically convert at least a part of light transmitted through the first filter portion; and
a second filter portion arranged between the first filter portion and the photoelectric conversion portion and configured to suppress light of a higher-order mode included in the light transmitted through the first filter portion.
(2) The solid-state imaging apparatus according to claim 1, wherein the first filter portion includes a plurality of pixel blocks periodically arranged in a planar direction,
the pixel blocks each include a plurality of the first filter portions respectively configured to selectively transmit light of a different wavelength range, and
the second filter portion is configured to suppress light of a higher-order mode included in light transmitted through the plurality of first filter portions.
(3) The solid-state imaging apparatus according to (1) or (2), wherein the second filter portion includes a substrate including a compound semiconductor material.
(4) The solid-state imaging apparatus according to (3), wherein the substrate is an InP substrate.
(5) The solid-state imaging apparatus according to (3) or (4), wherein the substrate has a thickness of 1000 nm or more.
(6) The solid-state imaging apparatus according to (3) or (4), wherein the second filter portion is arranged between the substrate and the photoelectric conversion portion and includes a buffer layer configured to lattice-match with the substrate.
(7) The solid-state imaging apparatus according to (6), wherein the buffer layer includes an InGaAsP layer or an InGaAlAs layer.
(8) The solid-state imaging apparatus according to (7), wherein the buffer layer has a thickness of 1000 nm or more.
(9) The solid-state imaging apparatus according to (7) or (8), wherein the buffer layer has a multiple quantum well structure.
(10) The solid-state imaging apparatus according to (9), wherein the buffer layer has a quantum structure including at least one of an InP layer, an InGaAs layer, and an InGaP layer.
(11) The solid-state imaging apparatus according to (9), wherein the buffer layer has a quantum structure in which an InGaAs layer or an InGaP layer, and an InP layer, are alternately arranged.
(12) The solid-state imaging apparatus according to any one of (1) to (11), wherein the second filter portion is configured to suppress wavelength components of under 1000 nm included in light transmitted through the first filter portion.
(13) The solid-state imaging apparatus according to any one of (1) to (12), wherein the first filter portion has a multi-layer film including an amorphous silicon film.
(14) The solid-state imaging apparatus according to (13), wherein
the first filter portion includes resonators configured to perform refractive-index modulation of light in pixel units, and
the multi-layer film is arranged on both surface sides of the resonators.
(15) The solid-state imaging apparatus according to (14), wherein
at least a part of the resonators among the resonators provided in pixel units includes a cavity having intrinsic refractive characteristics.
(16) A manufacturing method of a solid-state imaging apparatus, including the steps of:
forming a photoelectric conversion layer on a first principal surface of a substrate including a compound semiconductor material;
reducing a thickness of the substrate by grinding a side of a second principal surface on an opposite side to the first principal surface of the substrate;
forming a first multi-layer film on the second principal surface of the substrate, the first multi-layer film having a first film and a second film with different refractive indices being alternately arranged;
forming a resonator by forming, on the first multi-layer film, a resonator base layer using the first film or the second film as a material,
forming a cavity of a different size for each pixel in the base layer, and filling an inside of the cavity with the material of the second film when the base layer is the first film but filling the inside of the cavity with the material of the first film when the base layer is the second film; and
forming, on the base layer, a second multi-layer film in which the first film and the second film are alternately arranged, wherein
the step of forming a resonator includes the steps of:
forming a plurality of first grooves on the base layer in a first direction on a plane of the base layer;
forming a plurality of second grooves on the base layer in a second direction which intersects with the first direction on the plane of the base layer; and
forming the resonator by filling the plurality of first grooves and the plurality of second grooves with the material of the second film when the base layer is the first film but filling the plurality of first grooves and the plurality of second grooves with the material of the first film when the base layer is the second film.
(17) The manufacturing method according to (16), wherein
in the step of reducing a thickness of the substrate, the thickness of the substrate is set to 1000 nm or more.
(18) The manufacturing method according to (16) or (17), including
the step of forming a buffer layer which lattice-matches with the substrate on the second principal surface of the substrate after reducing the thickness of the substrate, wherein
the first multi-layer film is formed on the buffer layer.
(19) The manufacturing method according to (18), wherein
in the step of forming the buffer layer, a thickness of the buffer layer is set to 1000 nm or more.
(20) The manufacturing method according to (18) or (19), wherein
in the step of forming the buffer layer, a quantum structure in which an InGaAs layer or an InGaP layer, and an InP layer, are alternately arranged is formed.

Aspects of the present disclosure are not limited to the individual embodiments described above and include various modifications which those skilled in the art can arrive at, and advantageous effects of the present disclosure are also not limited to the contents described above. In other words, various additions, modifications, and partial deletions can be made without departing from the conceptual thoughts and the gist of the present disclosure that can be derived from the contents defined in the claims and equivalents thereof.

### REFERENCE SIGNS LIST

1 Solid-state imaging apparatus
2 First filter portion
3 Second filter portion
4 Photoelectric conversion portion
5 First multi-layer film
6 Resonator
7 Second multi-layer film
8 Amorphous silicon film
9 SiO₂ layer
11 InP substrate
12 ITO film
13 Pixel block
14 Microstructure
15 Buffer layer
15a InGaAsP layer
15b InGaAlAs layer
16 p-InGaAs crystal
17 Photoresist
18 Cavity

1. A solid-state imaging apparatus, comprising:
a first filter portion having a Fabry-Perot resonator configured to resonate light of a predetermined wavelength range between two reflection surfaces, the first filter portion being configured to selectively transmit light of the predetermined wavelength range;
a photoelectric conversion portion configured to photoelectrically convert at least a part of light transmitted through the first filter portion; and
a second filter portion arranged between the first filter portion and the photoelectric conversion portion and configured to suppress light of a higher-order mode included in the light transmitted through the first filter portion.

2. The solid-state imaging apparatus according to claim 1, wherein the first filter portion has a plurality of pixel blocks periodically arranged in a planar direction,
the pixel blocks each have a plurality of the first filter portions respectively configured to selectively transmit light of a different wavelength range, and the second filter portion is configured to suppress light of a higher-order mode included in light transmitted through the plurality of first filter portions.

3. The solid-state imaging apparatus according to claim 1, wherein the second filter portion has a substrate including a compound semiconductor material.

4. The solid-state imaging apparatus according to claim 3, wherein the substrate is an InP substrate.

5. The solid-state imaging apparatus according to claim 3, wherein the substrate has a thickness of 1000 nm or more.

6. The solid-state imaging apparatus according to claim 3, wherein the second filter portion is arranged between the substrate and the photoelectric conversion portion and has a buffer layer configured to lattice-match with the substrate.

7. The solid-state imaging apparatus according to claim 6, wherein
the buffer layer has an InGaAsP layer or an InGaAlAs layer.

8. The solid-state imaging apparatus according to claim 7, wherein
the buffer layer has a thickness of 1000 nm or more.

9. The solid-state imaging apparatus according to claim 7, wherein
the buffer layer has a multiple quantum well structure.

10. The solid-state imaging apparatus according to claim 9, wherein
the buffer layer has a quantum structure including at least one of an InP layer, an InGaAs layer, and an InGaP layer.

11. The solid-state imaging apparatus according to claim 9, wherein
the buffer layer has a quantum structure in which an InGaAs layer or an InGaP layer, and an InP layer, are alternately arranged.

12. The solid-state imaging apparatus according to claim 1, wherein
the second filter portion is configured to suppress wavelength components of under 1000 nm included in light transmitted through the first filter portion.

13. The solid-state imaging apparatus according to claim 1, wherein
the first filter portion has a multi-layer film including an amorphous silicon film.

14. The solid-state imaging apparatus according to claim 13, wherein
the first filter portion includes resonators configured to perform refractive-index modulation of light in pixel units, and
the multi-layer film is arranged on both surface sides of the resonators.

15. The solid-state imaging apparatus according to claim 14, wherein
at least a part of the resonators among the resonators provided in pixel units includes a cavity having intrinsic refractive characteristics.

16. A manufacturing method of a solid-state imaging apparatus, comprising the steps of:
forming a photoelectric conversion layer on a first principal surface of a substrate including a compound semiconductor material;
reducing a thickness of the substrate by grinding a side of a second principal surface on an opposite side to the first principal surface of the substrate;
forming a first multi-layer film on the second principal surface of the substrate, the first multi-layer film having a first film and a second film with different refractive indices being alternately arranged;
forming a resonator by forming, on the first multi-layer film, a base layer of a resonator using the first film or the second film as a material,
forming a cavity of a different size for each pixel in the base layer, and filling an inside of the cavity with the material of the second film when the base layer is the first film but filling the inside of the cavity with the material of the first film when the base layer is the second film; and
forming, on the base layer, a second multi-layer film in which the first film and the second film are alternately arranged, wherein
the step of forming a resonator includes the steps of:
forming a plurality of first grooves on the base layer in a first direction on a plane of the base layer;
forming a plurality of second grooves on the base layer in a second direction which intersects with the first direction on the plane of the base layer; and
forming the resonator by filling the plurality of first grooves and the plurality of second grooves with the material of the second film when the base layer is the first film but filling the plurality of first grooves and the plurality of second grooves with the material of the first film when the base layer is the second film.

17. The manufacturing method according to claim 16, wherein
in the step of reducing a thickness of the substrate, the thickness of the substrate is set to 1000 nm or more.

18. The manufacturing method according to claim 16, comprising the step of:
forming a buffer layer which lattice-matches with the substrate on the second principal surface of the substrate after reducing the thickness of the substrate, wherein
the first multi-layer film is formed on the buffer layer.

19. The manufacturing method according to claim 18, wherein
in the step of forming the buffer layer, a thickness of the buffer layer is set to 1000 nm or more.

20. The manufacturing method according to claim 18, wherein
in the step of forming the buffer layer, a quantum structure in which an InGaAs layer or an InGaP layer, and an InP layer, are alternately arranged is formed.
